(19) United States
(12) Patent Application Publication
(10) Pub. No.: US 2009/0121628 A1
(43) Pub. Date: May 14, 2009

(54) INORGANIC LIGHT EMITTING DEVICE

(75) Inventors: Don-Chan CHO, Seongnam-si (KR); Jae-Byung PARK, Seongnam-si (KR); Hae-Il PARK, Seoul (KR); Jin-Seob BYUN, Seoul (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 12/189,846

(22) Filed: Aug. 12, 2008

(30) Foreign Application Priority Data
Nov. 9, 2007 (KR) 10-2007-0114127

(51) Int. Cl. H01L 33/00

(52) U.S. Cl. 313/509

(57) ABSTRACT

An inorganic light emitting device includes a first emission layer that includes a first electrode, a first dielectric layer, a first sub-emission layer, a second dielectric layer and a first auxiliary electrode sequentially stacked on a substrate, a second emission layer that includes the first auxiliary electrode and a third dielectric layer, a second sub-emission layer, a fourth dielectric layer and a second auxiliary electrode sequentially stacked on the first auxiliary electrode, and a third emission layer that includes the second auxiliary electrode and a fifth dielectric layer, a third sub-emission layer, a sixth dielectric layer and a second electrode sequentially stacked on the second auxiliary electrode.

This application claims priority to Korean Patent Application No. 10-2007-114127, filed on Nov. 9, 2007, and all the benefits accruing therefrom under 35 U.S.C. §119, the contents of which in its entirety are herein incorporated by reference.

### BACKGROUND OF THE INVENTION

1. Field of the invention

The present invention relates to an inorganic light emitting device (“IOLED”). More particularly, the present invention relates to an IOLED which is capable of improving its luminance and efficiency.

2. Description of the Related Art

Generally, electroluminescent (“EL”) elements have been widely used for backlights owing to their advantages, such as a slim and light feature, uniform surface light emitting property, and easiness to manufacture. The EL elements can be classified into dispersion-type EL elements, thin film-type EL elements, and carrier injection-type EL elements. The dispersion-type EL elements include an emission layer which is formed by dispersing phosphors in a material of high permittivity. The thin film-type EL elements include an emission layer and an insulation layer, which are deposited to each other by electronic beams or high frequency sputtering. The carrier injection-type EL elements emit light at the time of recombination of electrons and holes.

Inorganic light emitting devices (“IOLEDs”), which have been highlighted in their early developing stage of EL elements, have had high voltage consumption, low brightness and efficiency. The IOLEDs, which are currently used for low-brightness emission devices, such as keypads or mood ramps, have less quality of color properties than liquid crystal displays (“LCDs”) due to their own limitations. This makes it difficult to apply the IOLEDs to displaying devices.

To allow the IOLEDs to be applicable to displaying devices, color conversion technologies and color filter technologies have been developed. The color filter technologies may improve color properties of the IOLEDs, but reduce self emission properties and efficiency as well.

### BRIEF SUMMARY OF THE INVENTION

The present invention provides an IOLED improving its luminance and efficiency by using voltage phase in an alternative current (“AC”) driving method.

In exemplary embodiments of the present invention, the IOLED may include a first emission layer, a second emission layer and a third emission layer. The first emission layer may include a first electrode, a first dielectric layer, a first sub-emission layer, a second dielectric layer and a first auxiliary electrode that are sequentially stacked on a substrate. The second emission layer may include the first auxiliary electrode and a third dielectric layer, a second sub-emission layer, a fourth dielectric layer and a second auxiliary electrode that are sequentially stacked on the first auxiliary electrode. The third emission layer may include the second auxiliary electrode and a fifth dielectric layer, a third sub-emission layer, a sixth dielectric layer and a second electrode that are sequentially stacked on the second auxiliary electrode.

The first to third sub-emission layers may be selectively formed of red, green and blue light emission layers. The red light emission layer may be formed of ZnS:Mn. The green light emission layer may be formed of ZnS:Tb. The blue light emission layer may be formed of a material including at least one of BaAl₂S₄:Eu, (Mg,Ba)Al₂S₄:Eu, CaGa₂S₄:Ce, SrS:Cu, SrS:Ce, CaS:Pb, SrGa₂S₄:Ce, ZnS:Tm and ZnS:Ag,Cl.

The first to sixth dielectric layers may be formed of a material including at least one of Y₂O₃, Ba₂O₃, Al₂O₃, Ta₂O₅, SiO₂, Si₃N₄, TiO₂, ATO, SrTiO₃, BaTiO₃, BaTa₂O₆ and PLZT.

AC voltages applied to the first and third emission layers may have an adverse phase of an AC voltage applied to the second emission layer. The AC voltages applied to the first to third emission layers may be controlled by switches.

The device may be a display and the first electrode, first auxiliary electrode, second auxiliary electrode, and the second electrode may each include a stripe pattern.

In other exemplary embodiments of the present invention, the IOLED may include a first emission layer, a second emission layer, a first color conversion layer, and a second color conversion layer. The first emission layer may include a first electrode, a first dielectric layer, a first sub-emission layer, a second dielectric layer, and an auxiliary electrode that are sequentially stacked on a substrate. The second emission layer may include the auxiliary electrode and a third dielectric layer, a second sub-emission layer, a fourth dielectric layer, and a second electrode sequentially that are stacked on the first auxiliary electrode. The first and second conversion layers are formed under the substrate.

The first and second emission layers may be blue emission layers formed of a material including at least one of BaAl₂S₄:Eu, (Mg,Ba)Al₂S₄:Eu, CaGa₂S₄:Ce, SrS:Cu, SrS:Ce, CaS:Pb, SrGa₂S₄:Ce, ZnS:Tm and ZnS:Ag,Cl.

The first color conversion layer compensates for red light and may be formed of a material including at least one of Y₂O₂S:Eu; La₂O₂S:Eu; Ba₃MgSi₂O₈:Eu,Mn; Sr₃MgSi₂O₈:Eu,Mn; Ca₃MgSi₂O₈:Eu,Mn; CaAlSiN₃:Eu; CaS:Eu; SrS:Eu and (Ba,Ca,Sr)₂Si₅N₈:Eu and the second conversion layer compensates for green light and may be formed of a material including at least one of SrGa2S4:Eu and SrSi2N2O2:Eu.

The device may be a display and the first electrode, the auxiliary electrode, and the second electrode may each include a stripe pattern.

In still other exemplary embodiments of the present invention, an IOLED may include a first emission layer, a second emission layer, and a first color conversion layer. The first emission layer may include a first electrode, a first dielectric layer, a first sub-emission layer, a second dielectric layer, and an auxiliary electrode sequentially stacked on a substrate. The second emission layer may include the auxiliary electrode and a third dielectric layer, a second sub-emission layer, a fourth dielectric layer and a second electrode that are sequentially stacked on the auxiliary electrode. The first color conversion layer may be formed under the substrate.

The first sub-emission layer emits blue light and may be formed of a material including at least one of BaAl₂S₄:Eu, (Mg,Ba)Al₂S₄:Eu, CaGa₂S₄:Ce, SrS:Cu, SrS:Ce, CaS:Pb, SrGa₂S₄:Ce, ZnS:Tm and ZnS:Ag,Cl.

The second sub-emission layer may be formed of yellow fluorescent material, such as YAG:Ce.

The first color conversion layer compensates for red light and may be formed of a material including at least one selected of Y₂O₂S:Eu; La₂O₂S:Eu; Ba₃MgSi₂O₈:Eu,Mn; Sr₃MgSi₂O₈:Eu,Mn; Ca₃MgSi₂O₈:Eu,Mn; CaAlSiN₃:Eu; CaS:Eu; SrS:Eu and (Ba,Ca,Sr)₂Si₅N₈:Eu.

The first to fourth dielectric layers may be formed of a material including at least one of Y₂O₃, Ba₂O₃, Al₂O₃, Ta₂O₅, SiO₂, Si₃N₄, TiO₂, ATO, SrTiO₃, BaTiO₃, BaTa₂O₆ and PLZT.

The device may be a display and the first electrode, the auxiliary electrode, and the second electrode may each include a stripe pattern.

### BRIEF DESCRIPTION OF THE DRAWINGS

The above and other features and advantages of the present invention will become more apparent by describing exemplary embodiments thereof with reference to the accompanying drawings, in which:

FIG. 1 is an exploded perspective view of an exemplary inorganic light emitting device (“IOLED”) according to a first exemplary embodiment of the present invention;

FIG. 2 is an exploded perspective view of an exemplary IOLED according to a second exemplary embodiment of the present invention;

FIG. 3 is an exploded perspective view of an exemplary IOLED according to a third exemplary embodiment of the present invention; and

FIG. 4 is an exploded perspective view of an exemplary IOLED according to a fourth exemplary embodiment of the present invention.

### DETAILED DESCRIPTION OF THE INVENTION

The invention now will be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present there between. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “includes” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to other elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present invention are described herein with reference to exploded perspective illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

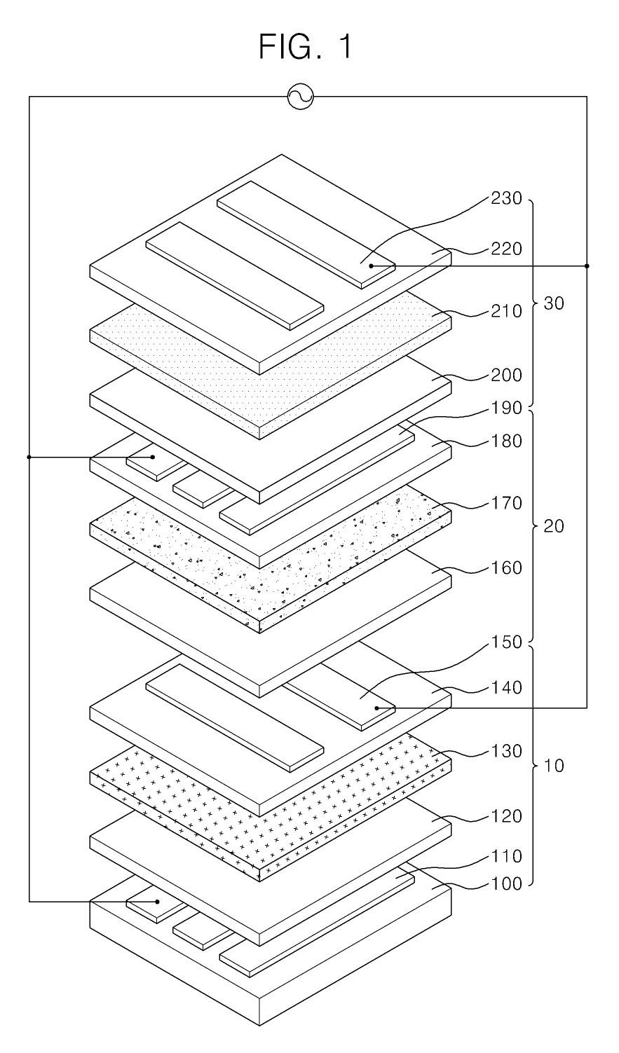

Hereinafter, exemplary embodiments of the present invention will be described in more detail with reference to FIGS. 1 to 4.

FIG. 1 is an exploded perspective view of an exemplary inorganic light emitting device (“IOLED”) according to a first exemplary embodiment of the present invention.

Referring to FIG. 1, the IOLED includes a first emission layer 10, a second emission layer 20, and a third emission layer 30. The first emission layer 10 includes an insulation substrate 100, a first electrode 110, a first dielectric layer 120, a first sub-emission layer 130, a second dielectric layer 140, and a first auxiliary electrode 150. The first electrode 110, first dielectric layer 120, first sub-emission layer 130, second dielectric layer 140, and first auxiliary electrode 150 are sequentially stacked on the insulation substrate 100. The second emission layer 20 includes the first auxiliary electrode 150, a third dielectric layer 160, a second sub-emission layer 170, a fourth dielectric layer 180, and a second auxiliary electrode 190 sequentially stacked on the first emission layer 10. The third emission layer 30 includes the second auxiliary electrode 190, a fifth dielectric layer 200, a third sub-emission layer 210, a sixth dielectric layer 220, and a second electrode 230 sequentially stacked on the second emission layer 30.

The first sub-emission layer 130 emits blue light and may be formed of a material including at least one of BaAl₂S₄:Eu, (Mg,Ba)Al₂S₄:Eu, CaGa₂S₄:Ce, SrS:Cu, SrS:Ce, CaS:Pb, SrGa₂S₄:Ce, ZnS:Tm, and ZnS:Ag,Cl.

The second emission layer 170 emits green light and may be formed of ZnS:Tb.

The third emission layer 210 emits red light and may be formed of ZnS:Mn.

Each of the first to the sixth dielectric layers 120, 140, 160, 180, 200 and 220 may be formed of a material including at least one of Y₂O₃, Ba₂O₃, Al₂O₃, Ta₂O₅, SiO₂, Si₃N₄, TiO₂, ATO, SrTiO₃, BaTiO₃, BaTa₂O₆ and PLZT.

The first electrode 110, and the first and second auxiliary electrodes 150 and 190 may be formed of at least one of indium tin oxide (“ITO”), tin oxide (“TO”), indium zinc oxide (“IZO”), and indium tin zinc oxide (“ITZO”).

The second electrode 230 may be formed of a metal having good reflectance, such as, but not limited to, aluminum (Al), magnesium (Mg), silver (Ag), and calcium (Ca), or a transparent electrode material, such as ITO, TO, IZO, and ITZO.

An alternative current (“AC”) voltage applied to the first emission layer 10 has the adverse phase of an AC voltage applied to the second emission layer 20, and the AC voltage applied to the second emission layer 20 has the adverse phase of an AC voltage applied to the third emission layer 30. By an adverse phase, it should be understood that the phase of the AC voltage applied to the first emission layer 10 is shifted in phase from the phase of the AC voltage applied to the second emission layer 20. For example, the phase of the AC voltage applied to the first emission layer 10 may be shifted by 180 degrees from the phase of the AC voltage applied to the second emission layer 20, such that the waveforms of the AC voltages applied to the first and second emission layers 10 and 20 are mirror images of each other. The AC voltage applied to the first emission layer 10 has the same phase as the AC voltage applied to the third emission layer 30.

The first sub-emission layer 130 is disposed between the first and second dielectric layers 120 and 140, the second sub-emission layer 170 between the third and fourth dielectric layers 160 and 180, and the third sub-emission layer 210 between the fifth and sixth dielectric layers 200 and 220. The first electrode 110 is disposed under the first dielectric layer 120, the first auxiliary electrode 150 between the second and third dielectric layers 140 and 160, the second auxiliary electrode 190 between the fourth and fifth dielectric layers 180 and 200, the second electrode 230 on the sixth dielectric layer 220. Light is emitted from the IOLED by the AC voltage applied to each of the electrodes 110, 150, 190, and 230.

When the AC voltage is applied to the electrodes disposed in each of the emission layers, electrons captured by the interface state are discharged into the inside of the conduction band. At this time, the electrons are accelerated to absorb enough energy to excite a luminescent center of the emission layers. Light is emitted when the excited electrons transit to the ground state. When the AC voltage of opposite polarity is applied to electrodes, the above process proceeds adversely. Accordingly, the IOLED may function not only as an on/off switch, but also as a dimming controllable backlight unit depending on the polarity of the voltage applied to the electrodes. The above-described stacked structure of the emission layers allows better emission efficiency of the IOLED than that of the conventional IOLED, even when the same voltage as that of the conventional IOLED is applied.

While the first to third light emission layers 10, 20 and 30 are described as emitting blue light, green light, and red light, respectively, the present invention is not limited thereto.

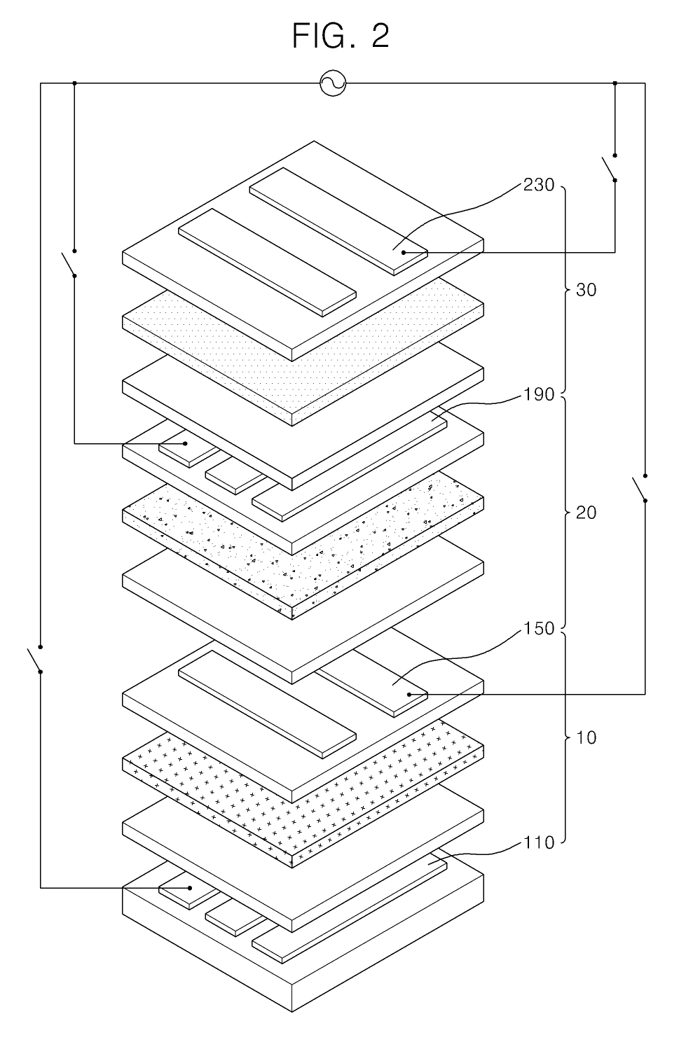

FIG. 2 is an exploded perspective view of the exemplary IOLED according to a second exemplary embodiment of the present invention.

Referring to FIG. 2, the IOLED includes switches in each of the first to third emission layers 10, 20 and 30. The AC voltages applied to the electrodes, which include the first electrode 110, the first auxiliary electrode 150, the second auxiliary electrode 190, and the second electrode 230, are controlled by the switches to adjust colors so that the IOLED may function as a display.

Except for controlling the voltages applied to the electrodes 110, 150, 190, and 230 through the switches, the IOLED according to the second exemplary embodiment of the present invention may have the same or substantially the same configuration as that of the first exemplary embodiment, therefore the detailed description will not be repeated.

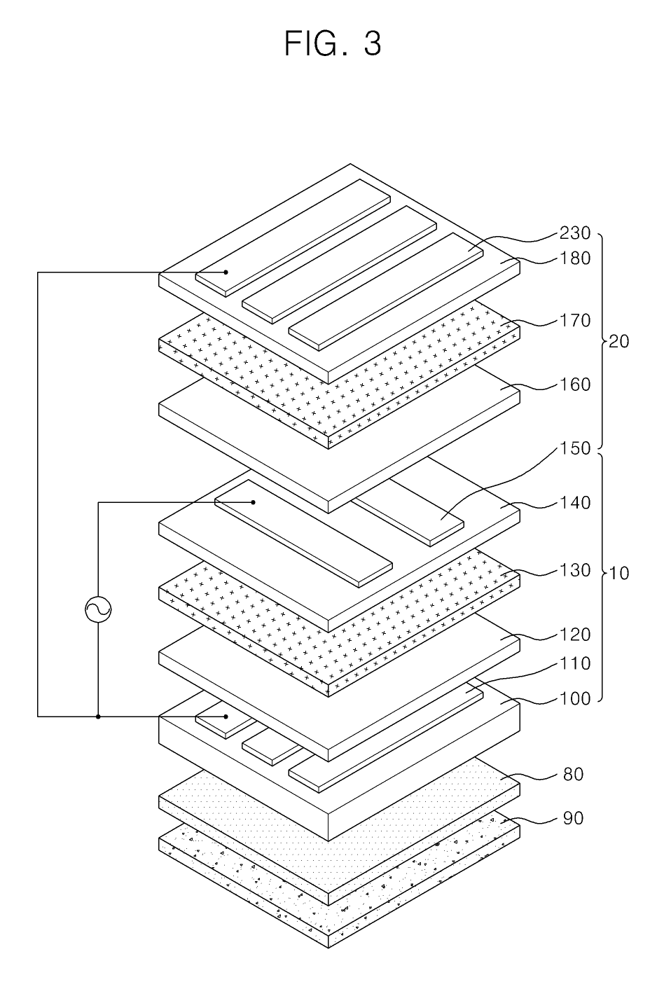

FIG. 3 is an enlarged perspective view of the exemplary IOLED according to a third exemplary embodiment of the present invention.

Referring to FIG. 3, the IOLED includes the first emission layer 10, the second emission layer 20, the first color conversion layer 80, and the second color conversion layer 90. The first emission layer 10 includes the insulation substrate 100, the first electrode 110, the first dielectric layer 120, the first sub-emission layer 130, the second dielectric layer 140 and the first auxiliary electrode 150. The first electrode 110, the first dielectric layer 120, the first sub-emission layer 130, the second dielectric layer 140 and the first auxiliary electrode 150 are sequentially stacked on the insulation substrate 100. The second emission layer 20 includes the first auxiliary electrode 150, the third dielectric layer 160, the second sub-emission layer 170, the fourth dielectric layer 180 and the second electrode 230, which are sequentially stacked on the first emission layer 10.

The first electrode 110 and the first auxiliary electrode 150 may be formed of a transparent electrode, such as ITO, TO, IZO, ITZO.

The second electrode 230 may be formed of a metal having good reflexibility, such as, but not limited to, Al, Mg, Ag, Ca, or a transparent material, such as, ITO, TO, IZO, ITZO.

Each of the first to fourth dielectric layers 120, 160, 160 and 180 may be formed of a material including at least one of Y₂O₃, Ba₂O₃, Al₂O₃, Ta₂O₅, SiO₂, Si₃N₄, TiO₂, ATO, SrTiO₃, BaTiO₃, BaTa₂O₆ and PLZT.

The first and second sub-emission layers 130 and 170 emit blue light and may be formed of a material including at least one of BaAl₂S₄:Eu, (Mg,Ba)Al₂S₄:Eu, CaGa₂S₄:Ce, SrS:Cu, SrS:Ce, CaS:Pb, SrGa₂S₄:Ce, ZnS:Tm and ZnS:Ag,Cl.

The first color conversion layer 80 compensates for red light and may be formed of a material including at least one of Y₂O₂S:Eu; La₂O₂S:Eu; Ba₃MgSi₂O₈:Eu,Mn; Sr₃MgSi₂O₈:Eu,Mn; Ca₃MgSi₂O₈:Eu,Mn; CaAlSiN₃:Eu; CaS:Eu; SrS:Eu and (Ba,Ca,Sr)₂Si₅N₈:Eu.

The second color conversion layer 90 compensates for green light and may be formed of a material including at least one of SrGa₂S₄:Eu and SrSi₂N₂O₂:Eu.

An AC voltage applied to the first emission layer 10 has an adverse phase of an AC voltage applied to the second emission layer 20. An AC driving method is identical to that of the first exemplary embodiment.

Since the conventional IOLED uses a single blue emission layer, and red and green color conversion layers, light efficiency is low. However, the IOLED of the present invention uses dual-stacked blue emission layers within first and second emission layers to improve the efficiency of the blue emission layer. This allows the IOLED to obtain twice higher light efficiency than the conventional IOLED at the same voltage as that applied to the conventional IOLED.

While this exemplary embodiment was described as an example of a stacked structure, where the first color conversion layer 80 that compensates for red light is formed on the second color conversion layer 90 that compensates for green light, the stacked structure is not limited thereto.

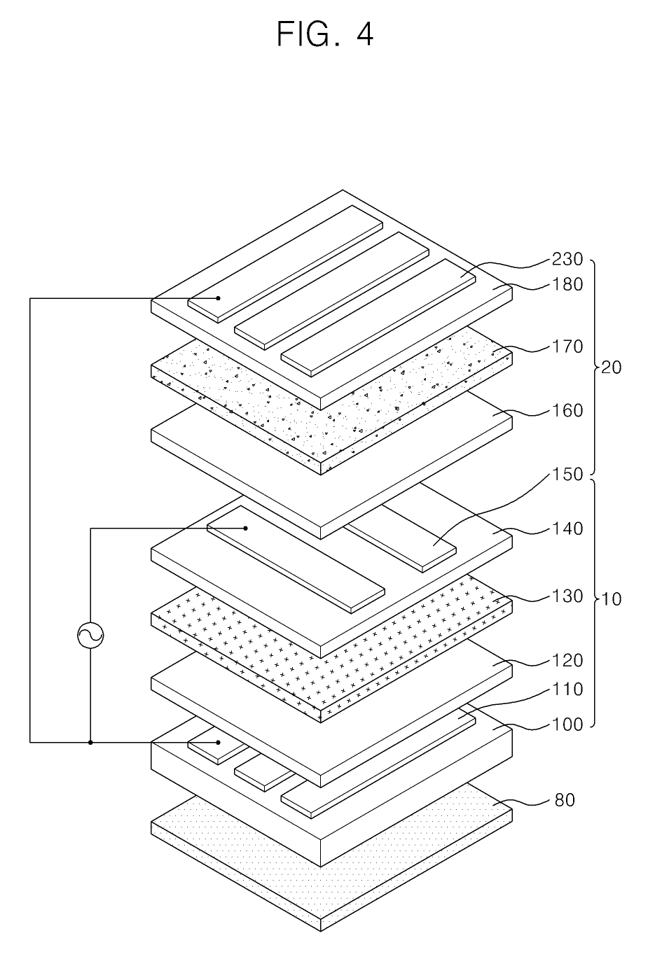

FIG. 4 is an exploded perspective view of an exemplary IOLED according to a fourth exemplary embodiment of the present invention.

Referring to FIG. 4, the IOLED device includes the first emission layer 10, the second emission layer 20, and the color conversion layer 80. The first emission layer 10 includes the insulation substrate 100, the first electrode 110, the first dielectric layer 120, the first sub-emission layer 130, the second dielectric layer 140, and the first auxiliary electrode 150. The first electrode 110, the first dielectric layer 120, the first sub-emission layer 130, the second dielectric layer 140, and the first auxiliary electrode 150 are sequentially stacked on the insulation substrate 100. The second emission layer 20 includes the first auxiliary electrode 150, the third dielectric layer 160, the second sub-emission layer 170, the fourth dielectric layer 180, and the second electrode 230 which are sequentially stacked on the first emission layer 10.

The first electrode 110 and the first auxiliary electrode 150 may be formed of the same transparent electrode material and the second electrode 230 may be formed of the same metal electrode material as previously described with respect to the third exemplary embodiment as shown in FIG. 3.

Each of the first to fourth dielectric layers 120, 140, 160 and 180 may be formed of a material including at least one of Y₂O₃, Ba₂O₃, Al₂O₃, Ta₂O₅, SiO₂, Si₃N₄, TiO₂, ATO, SrTiO₃, BaTiO₃, BaTa₂O₆ and PLZT.

The first sub-emission layer 130 emits blue light and may be formed of a material including at least one of BaAl₂S₄:Eu, (Mg,Ba)Al₂S₄:Eu, CaGa₂S₄:Ce, SrS:Cu, SrS:Ce, CaS:Pb, SrGa₂S₄:Ce, ZnS:Tm and ZnS:Ag,Cl.

The second sub-emission layer 170 emits yellow light and maybe formed of a fluorescent material, such as YAG:Ce. Light passes through the first sub-emission layer 130 and the second sub-emission layer 170 to emit light of a white color. However, since the IOLED does not provide sufficient red light to function as the backlight, the color conversion layer 80 that compensates for red light may be included therein.

The color conversion layer 80 that compensates for red light may be formed of a material including at least one of Y₂O₂S:Eu; La₂O₂S:Eu; Ba₃MgSi₂O₈:Eu,Mn; Sr₃MgSi₂O₈:Eu,Mn; Ca₃MgSi₂O₈:Eu,Mn; CaAlSiN₃:Eu; CaS:Eu; SrS:Eu and (Ba,Ca,Sr)₂Si₅N₈:Eu.

The AC voltage applied to the first emission layer 10 has the adverse phase of the AC voltage applied to the second emission layer 20. The AC driving method may be identical to or substantially the same as the AC driving method according to the first exemplary embodiment. Accordingly, the IOLED having the above configuration may function as an improved backlight or display.

In the IOLED according to exemplary embodiments, the electrodes may be formed in a stripe-like pattern to function as the display and may be formed in a plane-like pattern to function as the backlight.

According to the present invention, by stacking the inorganic emission layers thereon and applying the AC voltage to the electrodes, which include the electrodes and the auxiliary electrodes, to have adverse phase from each other, it is possible to improve its luminance and efficiency even though the voltages applied are the same as voltages applied to the conventional IOLED.

Although exemplary embodiments of the present invention have been described, it is understood that the present invention should not be limited to these exemplary embodiments but various changes and modification can be made by one or ordinary skill in the art within the spirit and scope of the present invention as hereinafter claimed.

What is claimed is:

1. An inorganic light emitting device comprising:
a first emission layer that comprises a first electrode, a first dielectric layer, a first sub-emission layer, a second dielectric layer, and a first auxiliary electrode sequentially stacked on a substrate;
a second emission layer that comprises the first auxiliary electrode, and a third dielectric layer, a second sub-emission layer, a fourth dielectric layer, and a second auxiliary electrode sequentially stacked on the first auxiliary electrode; and
a third emission layer that comprises the second auxiliary electrode, and a fifth dielectric layer, a third sub-emission layer, a sixth dielectric layer, and a second electrode sequentially stacked on the second auxiliary electrode.

2. The inorganic light emitting device according to claim 1, wherein the first, second, and third sub-emission layers are selectively formed of red, green and blue light emission layers.

3. The inorganic light emitting device according to claim 2, wherein the red light emission layer is formed of ZnS:Mn.

4. The inorganic light emitting device according to claim 2, wherein the green light emission layer is formed of ZnS:Tb.

5. The inorganic light emitting device according to claim 2, wherein the blue light emission layer is formed of a material including at least one of BaAl₂S₄:Eu, (Mg,Ba)Al₂S₄:Eu, CaGa₂S₄:Ce, SrS:Cu, SrS:Ce, CaS:Pb, SrGa₂S₄:Ce, ZnS:Tm, and ZnS:Ag,Cl.

6. The inorganic light emitting device according to claim 1, wherein the first to sixth dielectric layers are formed of a material including at least one of Y₂O₃, Ba₂O₃, Al₂O₃, Ta₂O₅, SiO₂, Si₃N₄, TiO₂, ATO, SrTiO₃, BaTiO₃, BaTa₂O₆, and PLZT.

7. The inorganic light emitting device according to claim 1, wherein AC voltages applied to the first and third emission layers have an adverse phase of an AC voltage applied to the second layer.

8. The inorganic light emitting device according to claim 1, wherein AC voltages applied to the first to third emission layers are controlled by switches.

9. The inorganic light emitting device according to claim 1, wherein the device is a display and the first electrode, first auxiliary electrode, second auxiliary electrode, and the second electrode each include a stripe pattern.

10. An inorganic light emitting device comprising:
a first emission layer that comprises a first electrode, a first dielectric layer, a first sub-emission layer, a second dielectric layer, and an auxiliary electrode sequentially stacked on a substrate;
a second emission layer that comprises the auxiliary electrode, and a third dielectric layer, a second sub-emission layer, a fourth dielectric layer, and a second electrode sequentially stacked on the auxiliary electrode; and
a first color conversion layer and a second color conversion layer formed under the substrate.

11. The inorganic light emitting device according to claim 10, wherein the first and second emission layers are blue emission layers formed of a material including at least one of BaAl₂S₄:Eu, (Mg,Ba)Al₂S₄:Eu, CaGa₂S₄:Ce, SrS:Cu, SrS:Ce, CaS:Pb, SrGa₂S₄:Ce, ZnS:Tm and ZnS:Ag,Cl.

12. The inorganic light emitting device according to claim 10, wherein the first color conversion layer compensates for red light and is formed of a material including at least one of Y₂O₂S:Eu; La₂O₂S:Eu; Ba₃MgSi₂O₈:Eu,Mn; Sr₃MgSi₂O₈:Eu,Mn; Ca₃MgSi₂O₈:Eu,Mn; CaAlSiN₃:Eu; CaS:Eu; SrS:Eu, and (Ba,Ca,Sr)₂Si₅N₈:Eu, and the second conversion layer compensates for green light and is formed of a material including at least one of SrGa₂S₄:Eu and SrSi₂N₂O₂:Eu.

13. The inorganic light emitting device according to claim 10, wherein the first to fourth dielectric layers are formed of a material including at least one of Y₂O₃, Ba₂O₃, Al₂O₃, Ta₂O₅, SiO₂, Si₃N₄, TiO₂, ATO, SrTiO₃, BaTiO₃, BaTa₂O₆, and PLZT.

14. The inorganic light emitting device according to claim 10, wherein the device is a display and the first electrode, the auxiliary electrode, and the second electrode each include a stripe pattern.

15. An inorganic light emitting device comprising:
a first emission layer that comprises a first electrode, a first dielectric layer, a first sub-emission layer, a second dielectric layer, and an auxiliary electrode sequentially stacked on a substrate;
a second emission layer that comprises the auxiliary electrode, and a third dielectric layer, a second sub-emission layer, a fourth dielectric layer, and a second electrode sequentially stacked on the auxiliary electrode; and
a color conversion layer formed under the substrate.

16. The inorganic light emitting device according to claim 15, wherein the first sub-emission layer emits blue light and is formed of a material including at least one of BaAl₂S₄:Eu, (Mg,Ba)Al₂S₄:Eu, CaGa₂S₄:Ce, SrS:Cu, SrS:Ce, CaS:Pb, SrGa₂S₄:Ce, ZnS:Tm, and ZnS:Ag,Cl.

17. The inorganic light emitting device according to claim 15, wherein the second sub-emission layer is formed of yellow fluorescent material including YAG:Ce.

18. The inorganic light emitting device according to claim 15, wherein the color conversion layer compensates for red light and is formed of a material including at least one of Y₂O₂S:Eu; La₂O₂S:Eu; Ba₃MgSi₂O₈:Eu,Mn; Sr₃MgSi₂O₈:Eu,Mn; Ca₃MgSi₂O₈:Eu,Mn; CaAlSiN₃:Eu; CaS:Eu; SrS:Eu, and (Ba,Ca,Sr)₂Si₅N₈:Eu.

19. The inorganic light emitting device according to claim 15, wherein the first to fourth dielectric layers are formed of a material including at least one of Y₂O₃, Ba₂O₃, Al₂O₃, Ta₂O₅, SiO₂, Si₃N₄, TiO₂, ATO, SrTiO₃, BaTiO₃, BaTa₂O₆, and PLZT.

20. The inorganic light emitting device according to claim 15, wherein the device is a display and the first electrode, the auxiliary electrode, and the second electrode each include a stripe pattern.
